(19) United States
(12) Patent Application Publication
(10) Pub. No.: US 2003/0034817 A1
(43) Pub. Date: Feb. 20, 2003

(54) Apparatus for reducing a magnitude of a rate of current change of an integrated circuit

(76) Inventors: Claude R. Gauthier, Fremont, CA (US); Tyler J. Thorp, Sunnyvale, CA (US); Richard L. Wheeler, San Jose, CA (US); Brian W. Amick, Austin, TX (US)

Correspondence Address: ROSENTHAL & OSHA L.L.P., 1221 MCKINNEY AVENUE, SUITE 2800, HOUSTON, TX, 77010, US

(21) Appl. No.: 09/930,030

(22) Filed: Aug. 14, 2001

(51) Int. Cl. H03K 5/12

(52) U.S. Cl. 327/170

(57) ABSTRACT

An apparatus for reducing a magnitude of a rate of current change of an integrated circuit is provided. The method uses a counter stage controlled by a control stage to sequentially disable a plurality of transistors that are used to source current from a power supply. By sequentially disabling the plurality of transistors, a reduction of an amount of current occurs gradually, effectively reducing the magnitude of the rate of current change.

### BACKGROUND OF INVENTION

As technology improves, integrated circuits, such as microprocessors, continue to become faster and more powerful. However, the benefits of increased speed and higher data throughput must be balanced with the costs of increased power consumption and higher operating temperatures.

When a microprocessor (also known in the art as a “central processing unit” or “CPU”) approaches or exceeds a certain power or temperature threshold, the microprocessor must be powered down to avoid microprocessor malfunction or damage. For example, if a microprocessor's cooling system fails, the microprocessor must be shut down quickly in order to avoid overheating. Similarly, if a microprocessor is drawing power in a manner that adversely affects other computer chip components, the microprocessor must be powered down to avoid undesirable effects.

However, the high-power nature of a microprocessor makes it difficult to power the microprocessor down instantly because doing so might cause damage to a computer chip's power supplies. The magnitude of such an instant change in current would be so high that a large change in voltage might result potentially damaging not only power supplies, but also computer chip components. Equation 1 shows the relationship between voltage, change in time, and change in current:

V=Z*i (1)

where V represents voltage, Z represents impedance, and i represents current. Thus, it follows that when i is instantly decreased, V decreases at a rate that a typical computer chip cannot sustain.

FIG. 1 shows a typical relationship (10) between current and time when power to a microprocessor, or other integrated circuit, is decreased instantly to a desired level. Particularly, FIG. 1 shows the rate of current change, Δi/Δt, when current is reduced from 10 amps to 5 amps.

### SUMMARY OF THE INVENTION

According to one aspect of the present invention, an apparatus for reducing a magnitude of a rate of current change of an integrated circuit comprises a control stage that generates a control signal dependent on whether power consumption by the integrated circuit needs to be reduced, and a counter stage that inputs the control signal and generates a plurality of sequential signals to a plurality of transistors, where the plurality of transistors source current from a power supply.

According to another aspect, a circuit for reducing a rate of current change of a microprocessor comprises a control stage that is connected to a power terminal and a ground terminal, where the control stage generates a control signal, and a counter stage that inputs the control signal and a clock signal, where the counter stage generates a first signal to a gate terminal of a first transistor.

Other aspects and advantages of the invention will be apparent from the following description and the appended claims.

### BRIEF DESCRIPTION OF DRAWINGS

FIG. 1 shows a typical relationship between current and time when power is reduced.

FIG. 2a shows a diagram of a circuit in accordance with an embodiment of the present invention.

FIG. 2b shows a relationship between current and time in accordance with the embodiment shown in FIG. 2a.

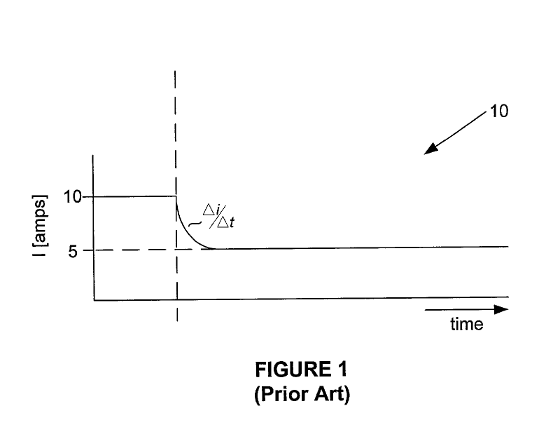

### DETAILED DESCRIPTION

The present invention relates to a method and apparatus for reducing a magnitude of a rate of current change of a microprocessor or other integrated circuit. Further, the present invention relates to a method and apparatus for powering down a microprocessor or other integrated circuit. Further, the present invention relates to a method and apparatus for cooling down a microprocessor or other integrated circuit.

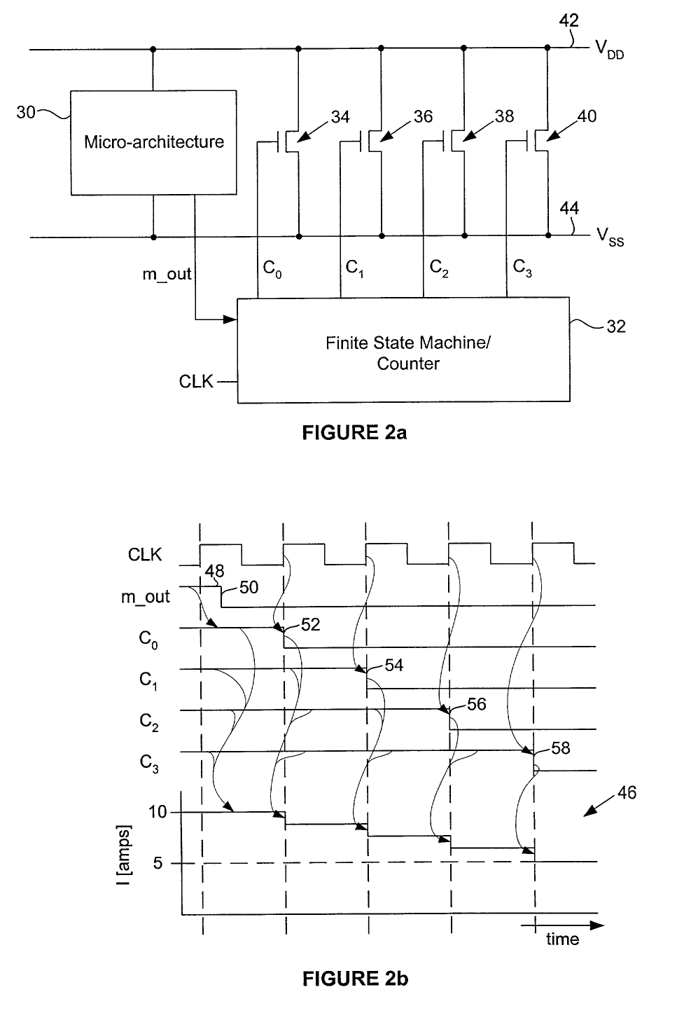

FIG. 2a shows a diagram of an exemplary circuit in accordance with an embodiment of the present invention. Particularly, FIG. 2a shows a micro-architectural block (also referred to as “micro-architectural stage”) (30) that generates a signal, m_out, to control a counter block (also referred to as “counter stage”) (32), where the counter block (32) may include a finite state machine such as a counter (not shown). The counter block (32), which inputs a clock signal, CLK, for timing and counting purposes, generates signals, C₀, C₁, C₂, and C₃, to a first transistor (34), a second transistor (36), a third transistor (38), and a fourth transistor (40), respectively. When a particular transistor shown in FIG. 2a is ‘on,’ i.e., enabled, that particular transistor behaves as a current source in that it sources current from V_{DD} (42) to V_{SS} (44). When a particular transistor is ‘off,’ i.e., is disabled, the current sourced through that particular transistor is decreased.

The counter block (32) generates a low signal successively on C₀, C₁, C₂, and C₃ on positive edges of CLK. However, those skilled in the art will appreciate that in other embodiments, the counter block (32) may be designed differently.

Those skilled in the art will also appreciate that in other embodiments, a different amount of signals generated by the counter block (32) may be used. Further, those skilled in the art will appreciate that in other embodiments, a different amount of transistors may be used. Further, those skilled in the art will appreciate that the micro-architectural block (30) may be a thermal sensor that is used to power down a microprocessor when the microprocessor is about to or begins to overheat.

FIG. 2b shows a relationship (46) between current and time based on the signals and circuit shown in FIG. 2a. When m_out is high (48), the counter block (32) generates high values on C₀, C₁, C₂, and C₃, where, in turn, the first, second, third, and last transistors (34, 36, 38, 40) are all switched ‘on.’ In this case, the transistors (34, 36, 38, 40) collectively source 10 amps from V_{DD} (42) to V_{SS} (44).

When m_out goes low (50), the counter block (32) generates low values on C₀, C₁, C₂, and C₃ successively at positive edges on CLK. Thus, at the first positive edge on CLK after m_out goes low (50), the counter block (32) generates a low value on C₀ (52), which, in turn, causes the first transistor (34) to switch ‘off,’ effectively reducing the collective current sourced by the transistors (34, 36, 38, 40) from V_{DD} (42) to V_{SS} (44). At the next positive edge on CLK, the counter block (32) generates a low value on C₁ (54), which, in turn, causes the second transistor (36) to switch ‘off,’ effectively reducing the collective current sourced by the transistors (34, 36, 38, 40) from V_{DD} (42) to V_{SS} (44). At the next positive edge on CLK, the counter block (32) generates a low value on C₂ (56), which, in turn, causes the third transistor (38) to switch ‘off,’ effectively reducing the collective current sourced by the transistors (34, 36, 38, 40) from V_{DD} (42) to V_{SS} (44). At the next positive edge on CLK after m_out goes low (50), the counter block (32) generates a low value on C₃ (58), which, in turn, causes the last transistor (40) to switch ‘off,’ effectively reducing the collective current sourced by the transistors (34, 36, 38, 40) from V_{DD} (42) to V_{SS} (44).

Those skilled in the art will appreciate that whenever a transistor is disabled, the amount of reduction of current sourced from V_{DD} (42) to V_{SS} (44) is less than in the case where only one transistor is used to source current from V_{DD} (42) to V_{SS} (44). Thus, by gradually reducing the current sourced from V_{DD} (42) to V_{SS} (44), the magnitude of the rate of current change, or Δi/Δt, is less than in the case where the current reduction is effected by simply instantly reducing the current to a desired level.

Advantages of the present invention may include one or more of the following. In some embodiments, because a plurality of transistors are used to reduce power consumption, a magnitude of a rate of current change of a microprocessor is reduced, and the microprocessor runs quieter, i.e., less noise, than when only one transistor is used to reduce power consumption.

In some embodiments, because a magnitude of a rate of current change of a microprocessor is reduced gradually as opposed to suddenly, the microprocessor operates faster.

In some embodiments, because a magnitude of a rate of current change of a microprocessor is reduced gradually instead of suddenly, the chance of power supply damage is reduced.

In some embodiments, because a magnitude of a rate of current change of a microprocessor is reduced gradually as opposed to suddenly, the effect on average power consumption is reduced.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An apparatus for reducing a magnitude of a rate of current change of an integrated circuit, comprising:
a control stage that generates a control signal dependent on whether power consumption by the integrated circuit needs to be reduced; and
a counter stage that inputs the control signal and generates a plurality of sequential signals to a plurality of transistors, wherein the plurality of transistors source current from a power supply.

2. The apparatus of claim 1, wherein the counter stage sequentially disables the plurality of transistors to cause a gradual reduction in an amount of current sourced from the power supply.

3. The apparatus of claim 2, wherein the counter stage enables the plurality of transistors when power consumption by the integrated circuit does not need to be reduced.

4. The apparatus of claim 1, wherein the plurality of transistors are each one selected from the group consisting of a p-type transistor and a n-type transistor.

5. A circuit for reducing a rate of current change of a microprocessor, comprising:
a control stage that is connected to a power terminal and a ground terminal, wherein the control stage generates a control signal; and
a counter stage that inputs the control signal and a clock signal, wherein the counter stage generates a first signal to a gate terminal of a first transistor.

6. The circuit of claim 5, wherein the first transistor has a terminal connected to power and another terminal connected to ground, and wherein the first transistor sources current from power to ground.

7. The circuit of claim 5, wherein the counter stage generates a second signal to a gate terminal of a second transistor.

8. The circuit of claim 7, wherein the second transistor has a terminal connected to power and another terminal connected to ground, and wherein the second transistor sources current from power to ground.

9. The circuit of claim 5, wherein the counter stage generates a last signal to a gate terminal of a last transistor.

10. The circuit of claim 9, wherein the last transistor has a terminal connected to power and another terminal connected to ground, and wherein the last transistor sources current from power to ground.
